(19) United States
(12) Patent Application Publication
(10) Pub. No.: US 2026/0072356 A1
(43) Pub. Date: Mar. 12, 2026

(54) SELECTIVE DEPOSITION AND PATTERN TRANSFER FOR CHEMICALLY AMPLIFIED RESISTS

(71) Applicant: Applied Materials, Inc., Santa Clara, CA (US)

(72) Inventors: NASRIN KAZEM, Santa Clara, CA (US); RUDY WOJTECKI, East Garrison, CA (US); SIVANANDHA KANAKASABAPATHY, Pleasanton, CA (US); LARRY GAO, Fremont, CA (US); LIKUN WANG, Cupertino, CA (US)

(21) Appl. No.: 19/310,018

(22) Filed: Aug. 26, 2025

Related U.S. Application Data
(60) Provisional application No. 63/692,621, filed on Sep. 9, 2024.

(51) Int. Cl. G03F 7/40; G03F 7/00; G03F 7/09; G03F 7/11; H01L 21/311

(52) U.S. Cl. CPC G03F 7/405; G03F 7/094; G03F 7/11; G03F 7/70033; H10P 50/73

(57) ABSTRACT

Embodiments described herein relate to a method that includes forming a resist layer over an underlayer that includes carbon and fluorine, and forming a pattern in the resist layer with a lithography process. In an embodiment, the method further includes selectively depositing a layer over surfaces of the resist layer. In an embodiment, the method further includes transferring the pattern into the underlayer with an etching process.

### CROSS-REFERENCE TO RELATED APPLICATIONS

This application claims the benefit of U.S. Provisional Application No. 63/692,621, filed on Sep. 9, 2024, the entire contents of which are hereby incorporated by reference herein.

### BACKGROUND

### 1) FIELD

Embodiments relate to the field of semiconductor manufacturing and, in particular, pattern transfer into an underlayer below a patterned chemically amplified resist (CAR) that is lined by a protective layer.

### 2) DESCRIPTION OF RELATED ART

Extreme ultraviolet (EUV) photoresists allow for the continued scaling to smaller features that are patterned on a semiconductor substrate. One limiting factor in the use of EUV photoresists is the high dose-to-size necessary to provide the chemical change within the EUV photoresist that enables patterning. In order to combat this issue, underlayers have been proposed. The underlayer is designed to add species into the overlying EUV photoresist when exposed to the EUV radiation. These additional species can be used by the EUV photoresist to increase the chemical reaction rate within the EUV photoresist in order to reduce the dose of EUV radiation needed to provide high quality pattern development. In this way, the EUV patterning efficiency can be improved by increasing throughput of the exposure process.

However, the pattern of the developed EUV photoresist needs to be transferred through the underlayer. This is typically done with an etching process. A potential issue arises when there is poor etch selectivity between the EUV photoresist and the underlayer. That is, the pattern transfer process into the underlayer may result in the etching of the EUV photoresist. In some cases, complete removal of the EUV photoresist is seen when the pattern is transferred into the underlayer. This can lead to poor pattern transfer into the remaining layers of the patterning stack.

### SUMMARY

Embodiments described herein relate to a method that includes forming a resist layer over an underlayer that includes carbon and fluorine, and forming a pattern in the resist layer with a lithography process. In an embodiment, the method further includes selectively depositing a layer over surfaces of the resist layer. In an embodiment, the method further includes transferring the pattern into the underlayer with an etching process.

Embodiments described herein relate to a method that includes forming an underlayer over a substrate, wherein the underlayer includes fluorine and carbon, and forming a chemically amplified resist (CAR) over the underlayer. In an embodiment, the method further includes patterning the CAR with an extreme ultraviolet (EUV) lithography process, and forming a layer over surfaces of the CAR, where portions of the underlayer are exposed through openings in the layer. In an embodiment, the method may further include etching a pattern into the underlayer.

Embodiments described herein relate to a method that includes providing a patterning stack with a chemically amplified resist (CAR) that is patterned over an underlayer that includes carbon and fluorine, and applying a protective layer over surfaces of the CAR with a dry deposition process that includes an organic precursor and/or an organometallic precursor. In an embodiment, carbon-fluorine bonds at a surface of the underlayer reduce deposition of the protective layer on the underlayer.

### BRIEF DESCRIPTION OF THE DRAWINGS

FIG. 1A is a cross-sectional illustration of a semiconductor device with a patterning stack that includes an underlayer and a patterned resist layer over the underlayer, in accordance with an embodiment.

FIG. 1B is a cross-sectional illustration of the semiconductor device in FIG. 1A after the pattern is transferred into the underlayer with poor etch selectivity, in accordance with an embodiment.

FIG. 2A-2F are cross-sectional illustrations that depict a process for transferring a pattern into an underlayer after the resist layer is protected by a selectively deposited protective layer, in accordance with an embodiment.

FIG. 3A-3C are cross-sectional illustrations that depict a process for transferring a pattern into an underlayer after the resist layer is treated and a protective layer is selectively deposited over the resist layer, in accordance with an embodiment.

FIG. 4 is a flow diagram that depicts a process for transferring a pattern into an underlayer with a resist layer that is covered by a protective layer, in accordance with an embodiment.

FIG. 5 is a flow diagram that depicts a process for transferring a pattern into an underlayer after the resist layer is treated and a protective layer is selectively formed over the resist layer, in accordance with an embodiment.

FIG. 6 illustrates a block diagram of an exemplary computer system that may be used in conjunction with a processing tool, in accordance with an embodiment.

### DETAILED DESCRIPTION

Embodiments described herein include processes for pattern transfer into an underlayer below a patterned chemically amplified resist (CAR) that is lined by a protective layer. In the following description, numerous specific details are set forth in order to provide a thorough understanding of embodiments. It will be apparent to one skilled in the art that embodiments may be practiced without these specific details. In other instances, well-known aspects are not described in detail in order to not unnecessarily obscure embodiments. Furthermore, it is to be understood that the various embodiments shown in the accompanying drawings are illustrative representations and are not necessarily drawn to scale.

Various embodiments or aspects of the disclosure are described herein. In some implementations, the different embodiments are practiced separately. However, embodiments are not limited to embodiments being practiced in isolation. For example, two or more different embodiments can be combined together in order to be practiced as a single device, process, structure, or the like. The entirety of various embodiments can be combined together in some instances. In other instances, portions of a first embodiment can be combined with portions of one or more different embodiments. For example, a portion of a first embodiment can be combined with a portion of a second embodiment, or a portion of a first embodiment can be combined with a portion of a second embodiment and a portion of a third embodiment.

The embodiments illustrated and discussed in relation to the figures included herein are provided for the purpose of explaining some of the basic principles of the disclosure. However, the scope of this disclosure covers all related, potential, and/or possible, embodiments, even those differing from the idealized and/or illustrative examples presented. This disclosure covers even those embodiments which incorporate and/or utilize modern, future, and/or as of the time of this writing unknown, components, devices, systems, etc., as replacements for the functionally equivalent, analogous, and/or similar, components, devices, systems, etc., used in the embodiments illustrated and/or discussed herein for the purpose of explanation, illustration, and example.

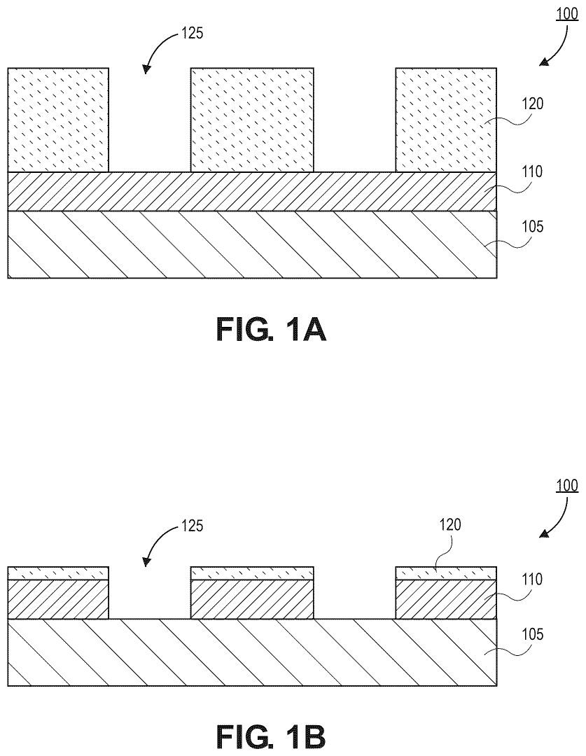

As noted above, resist layers in EUV lithography require high dosages in order to provide the desired pattern fidelity during development. Underlayers that can participate in the chemical conversion of the EUV resist material can be used in order to lower the necessary dose. This allows for an overall improvement in the throughput of the EUV lithography process. However, such underlayer materials tend to have poor etch selectivity to the overlying resist layer. That is, as the pattern is transferred into the underlayer, the overlying resist layer is also significantly etched. Such an issue is demonstrated in FIGS. 1A and 1B.

Referring now to FIG. 1A, a cross-sectional illustration of a device 100 is shown. The device 100 may comprise a patterning stack 105, an underlayer 110, and a resist layer 120. The patterning stack 105 may include one or more layers suitable for transferring a pattern into an underlying substrate (such as a semiconductor substrate, a silicon oxide layer over a substrate, a nitride layer over a substrate, or the like). The resist layer 120 may include a photosensitive material that undergoes a chemical change (e.g., a solubility switch, such as a deprotection reaction) upon exposure to EUV radiation. In some instances the underlayer 110 may also react to the EUV radiation and diffuse chemical species into the resist layer 120 in order to speed up, magnify, and/or otherwise enhance the solubility switch in the resist layer 120.

In the illustration of FIG. 1A, the resist layer 120 has been patterned with any suitable EUV lithography process. For example, the EUV lithography process may include an EUV exposure of selected regions of the resist layer 120, a bake, and a developing process. The EUV lithography process may result in the formation of a pattern 125 in the resist layer 120. In the illustration of FIG. 1A, the pattern 125 includes a plurality of trenches through the resist layer 120 that expose portions of the underlayer 110. Though, any suitable pattern may be formed in the resist layer 120 (e.g., holes for via openings, etc.).

Referring now to FIG. 1B, a cross-sectional illustration of the device 100 after the pattern 125 is transferred into the underlayer 110 is shown. The pattern 125 may be transferred into the underlayer 110 through the use of an etching process. However, it is difficult to engineer a high etch selectivity between the resist layer 120 and the underlayer 110 while maintaining the desired sensitivity of the system. Accordingly, the resist layer 120 may also undergo significant thickness reduction as a result of the etching process. While a small amount of the resist layer 120 remains in FIG. 1B as an example, in some instances the resist layer 120 may be completely depleted. The depletion of the resist layer 120 results in significant issues with downstream pattern transfer into the remainder of the patterning stack 105 and any other underlying layers.

Accordingly, embodiments disclosed herein leverage chemical differences between the resist layer and the underlayer in order to selectively deposit a protective layer over the surfaces of the resist layer. The protective layer may have a relatively high etch selectivity with the underlayer (compared to an etch selectivity between the underlayer and the resist layer). As such, the pattern can be transferred into the underlayer without significant impact to the structure of the resist layer. The additional etch resistance provided by the protective layer can also allow for a thickness of the resist layer to be reduced. Reducing the thickness of the resist layer enables EUV lithography to proceed with a lower dose in some instances as well. Therefore, the throughput through the EUV exposure tool may be increased in some embodiments.

In a particular embodiment, the underlayer comprises a fluorine doped carbon layer or any other suitable fluorocarbon film, and the resist layer comprises a chemically amplified resist (CAR). The underlayer may have surface dangling bonds that are primarily carbon-fluorine (C—F) bonds, and the CAR may have predominantly carbon-hydrogen (C—H) bonds. The C—H bonds at the surfaces of the CAR are significantly more reactive to organic precursors and/or organometallic precursors compared to the C—F bonds of the underlayer. As such, a subsequent dry deposition process (e.g., a chemical vapor deposition (CVD) process or an atomic layer deposition (ALD) process) using such precursors will result in the selective deposition of an organic protective layer and/or or organometallic protective layer on the surfaces of the CAR without significant formation of the protective layer over exposed surfaces of the underlayer. A subsequent etching process may transfer the pattern in the CAR into the unprotected underlayer.

In some embodiments, the selectivity of the deposition process for the protective layer may be further enhanced by the application of a treatment to the patterned resist layer. For example, the treatment may include an ultraviolet (UV) exposure and/or a EUV exposure. Such a blanket exposure of UV and/or EUV radiation initiates chemical reactions within the remaining portions of the resist layer. This can produce acid species and/or amine species at the surfaces of the resist layer (in addition to the existing C—H bonds). The addition of the acid and/or amine species can further enhance the reaction with the precursors used in the protective layer deposition process. This can lead to a faster protective layer deposition and/or better coverage of the surfaces of the resist layer by the protective layer.

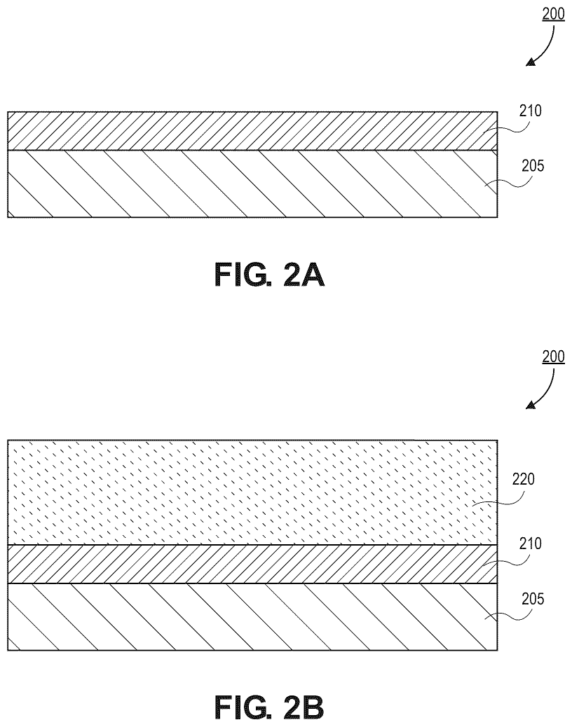

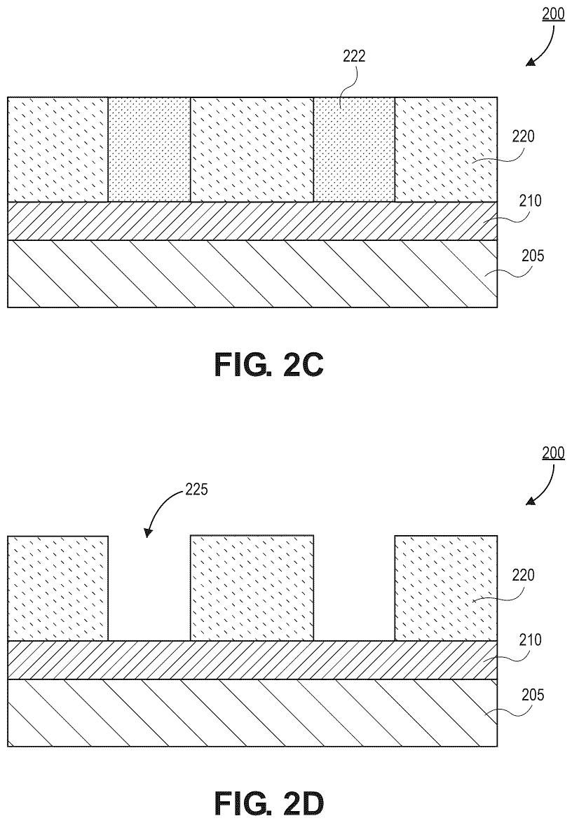

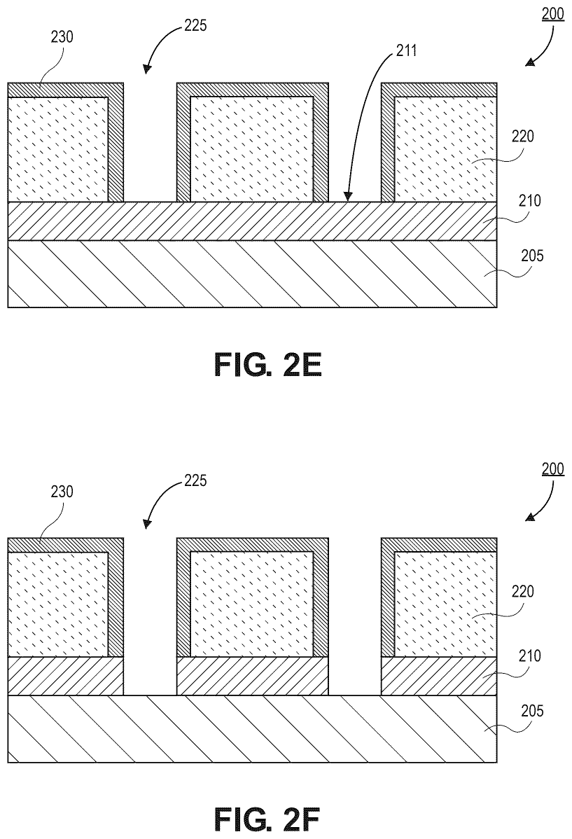

Referring now to FIG. 2A-2F, a series of cross-sectional illustrations depicting a process for transferring a pattern from a resist layer into an underlayer after selectively covering the surfaces of the resist layer with a protective layer is shown, in accordance with an embodiment. In an embodiment, the protective layer is selectively deposited over the resist layer without substantially covering the underlayer due to different surface chemistries. For example, the resist layer may have a relatively oleophilic surface and the underlayer may have a relatively oleophobic surface. The oleophilic surface enhances protective layer deposition, while the oleophobic surface minimizes protective layer deposition.

Referring now to FIG. 2A, a cross-sectional illustration of a portion of a device 200 with a patterning stack 205 and an underlayer 210 is shown, in accordance with an embodiment. In an embodiment, the patterning stack 205 may comprise any suitable material layer or layers for implementing a pattern transfer into an underlying substrate (not shown). The underlying substrate may be a semiconductor substrate with or without additional layers (e.g., oxide layers, nitride layers, metal layers, etc.).

In an embodiment, the patterning stack 205 may comprise a silicon and oxygen layer, such as a silicon oxide layer. For example, a tetraethyl orthosilicate (TEOS) based silicon oxide may be formed as a layer in the patterning stack 205. The patterning stack 205 may also comprise a carbon layer or the like. For example, the patterning stack 205 may comprise an amorphous carbon layer that is deposited with any suitable process, such as a CVD process or the like.

In an embodiment, the underlayer 210 may comprise carbon and fluorine. For example, the underlayer 210 may be a fluorine doped carbon film or a fluorocarbon-based polymer film. That is, the underlayer 210 may comprise fluorine and carbon. Due to the carbon and fluorine, the underlayer 210 may comprise C—F bonds at the surface of the underlayer. As will be described in greater detail herein, the C—F bonds may be used to prevent deposition of a protective layer. In an embodiment, the underlayer 210 may be deposited over the patterning stack 205 with any suitable process, such as a CVD process or an ALD process. Some suitable precursors may comprise CO, CF₄, CHF₃, or any other precursors comprising carbon and/or fluorine.

Referring now to FIG. 2B, a cross-sectional illustration of the device 200 after a resist layer 220 is formed over the underlayer 210 is shown, in accordance with an embodiment. In an embodiment, the resist layer 220 comprises a photoresist material that is sensitive to UV and/or EUV radiation. That is, exposure to UV and/or EUV radiation may drive a chemicals solubility switch (e.g., a deprotection reaction) within the exposed regions of the resist layer 220. In a particular embodiment, the resist layer 220 may comprise a CAR. The chemistry of the resist layer 220 may result in the formation of H—C bonds at the surface of the resist layer 220. The presence of the H—C bonds at the surface may be used to drive the selective deposition of the protective layer, as will be described in greater detail herein.

In an embodiment, the resist layer 220 may be applied over the underlayer 210 using any suitable process. For example, the resist layer 220 may be formed with a wet process (e.g., a spin coating process) or a dry process. A dry deposition process may include the use of CVD or ALD in order to deposit the resist layer 220. In the case of a dry deposition process for the resist layer 220, both the underlayer 210 and the resist layer 220 may be deposited within the same tool and/or chamber.

Referring now to FIG. 2C, a cross-sectional illustration of the device 200 after the resist layer 220 is exposed is shown, in accordance with an embodiment. In an embodiment, the resist layer 220 may be exposed in an UV exposure tool or an EUV exposure tool. The radiation may be selectively applied to the resist layer 220 (e.g., through a reticle, mask, or the like) in order to form a latent pattern 222 in the resist layer. The latent pattern 222 indicates portions of the resist layer 220 that have undergone a chemical reaction in order to switch the solubility of the resist layer 220. For example, in the case of a CAR, a deprotection reaction may occur in order to render the latent pattern 222 more susceptible to a developer chemistry than the unexposed regions of the resist layer 220.

In an embodiment, the UV or EUV exposure may also activate a chemical reaction in the exposed portions of the underlayer 210. The chemical reaction in the underlayer 210 may drive one or more reactive species into the overlying resist layer 220 (e.g., through diffusion) in order to participate in the chemical reaction that develops the latent pattern 222. As such, the presence of the underlayer 210 allows for a reduction in the dose necessary to provide the latent pattern 222 with a desired fidelity in the resist layer 220. In some embodiments, the device 200 may be baked (i.e., heated) after the exposure in order to enhance the chemical reaction within the resist layer 220.

Referring now to FIG. 2D, a cross-sectional illustration of the device 200 after a developing process is shown, in accordance with an embodiment. In an embodiment, the developing process may result in the removal of the latent pattern 222 in order to form a pattern 225 within the resist layer 220. The developing process may comprise a wet develop (i.e., a wet etch) to remove the latent pattern 222 to form the pattern 225. Due to the solubility switch in the latent pattern 222, the latent pattern 222 will be preferentially removed by the wet develop without significantly removing the unexposed regions of the resist layer 220. In the illustrated embodiment, the pattern 225 comprises a plurality of trenches that pass entirely through a thickness of the resist layer 220. Though, other patterns 225 or features may be formed through a thickness of the resist layer 220. For example, holes may be formed through the thickness of the resist layer 220 in order to form openings for vias in a layer underlying the patterning stack 205.

As shown, the pattern 225 exposes portions of a surface of the underlayer 210. In order to continue transferring the pattern 225 through the underlayer 210, an additional etching process may be used. However, as noted above, the etch selectivity between the underlayer 210 and the resist layer 220 may not be high enough to maintain the overlying resist layer 220 with a suitable thickness. That is, etching through the underlayer 210 may also remove a significant portion or substantially all of the resist layer 220. Accordingly, a protective layer may be applied over the resist layer 220, as will be shown herein.

Referring now to FIG. 2E, a cross-sectional illustration of the device 200 after a protective layer 230 is selectively applied over surfaces of the resist layer 220 is shown, in accordance with an embodiment. In an embodiment, the protective layer 230 may be formed over the top surface and sidewall surfaces of the resist layer 220. Additionally, the selective deposition allows for the exposed surfaces 211 of the underlayer 210 to remain uncovered. Stated differently, a substantial amount of the protective layer 230 may not deposit onto the exposed surfaces 211 of the underlayer 210.

In an embodiment, the protective layer 230 comprises a material that has an etch selectivity relative to the underlayer 210 that is higher than an etch selectivity of the underlayer 210 relative to the resist layer 220. As such, an etching process that removes the underlayer 210 may not substantially remove the protective layer 230. This allows for the structure of the resist layer 220 to remain through the transfer of the pattern 225 into the underlayer 210. In a particular embodiment, the protective layer 230 may comprise an organic material. Other embodiments may include a protective layer 230 that is an organometallic material. For example, the protective layer 230 may comprise one or more of BOₓ, BNₓ, TiOₓ, TiNₓ, TaOₓ, TaNₓ, HFOₓ, HfNₓ, C (e.g., graphite carbon), SiOₓ, SnOₓ, AlOₓ or GeOₓ.

In an embodiment, the protective layer 230 may be deposited with a dry deposition process, such as an ALD process or a CVD process. The deposition process may also be considered a thermal process with a deposition temperature of approximately 50° C. or higher. Though, lower temperatures may also e used for some ALD or CVD processes. Any suitable organic and/or organometallic precursors may be used to deposit the protective layer 230 on the resist layer 220. For example, precursors such as one or more of BBr₃, BCl₃, tris(dimethylamino)silane (TDMAS), bis(tert-butylamino)silane (BTBAS), hexamethyldisilazane (HMDS), tetrakis(dimethylamino)titanium (TDMAT), Pentakis(dimethylamido)tantalum (PDMAT), trimethylamine (TMA), triethylamine (TEA), tetraethyl orthosilicate (TEOS), tetramethyl orthosilicate (TMOS), B(Et)₃, B(Me)₃, B(OEt)₃, TiCl₄, TaCl₅, H₂O, or the like may be used to deposit the protective layer 230.

In an embodiment, the protective layer 230 is selectively deposited over the surfaces of the resist layer 220 by leveraging chemical differences between the surfaces of the resist layer 220 and the underlayer 210. As noted above, the underlayer 210 may comprise a surface 211 with C—F bonds that are relatively oleophobic, and the resist layer 220 may comprise a surface with H—C bonds that are relatively oleophilic. As such, the surfaces of the resist layer 220 are more reactive to the organometallic and/or organic precursors used to deposit the protective layer 230. This allows for the protective layer 230 to substantially surround the remaining structure of the resist layer 220 without significant deposition on the underlayer 210.

Referring now to FIG. 2F, a cross-sectional illustration of the device 200 after the pattern 225 is transferred into the underlayer 210 is shown, in accordance with an embodiment. In an embodiment, the pattern 225 may be transferred into the underlayer 210 through an etching process, such as a dry etching process. Due to the presence of the protective layer 230 over the resist layer 220, the structure of the resist layer 220 substantially persists after the etching process used to transfer the pattern 225 into the underlayer 210. In an embodiment, the etching process may comprise a plasma etch, such as one with a plasma resulting from one or more of O₂, CH₄, CF₄, or Cl₄.

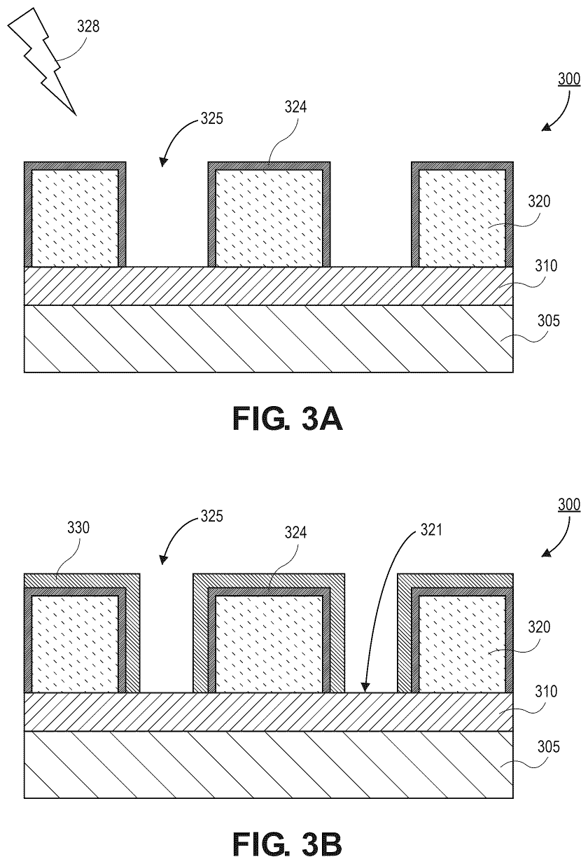

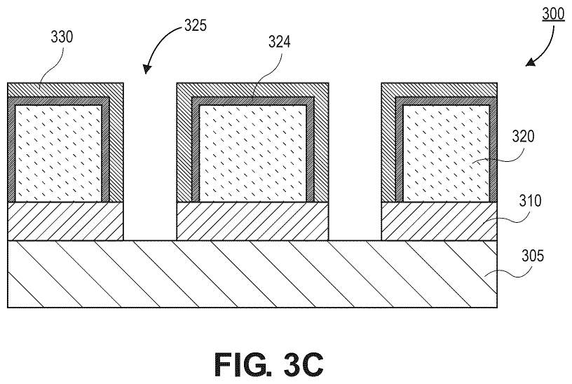

Referring now to FIG. 3A-3C, a series of illustrations depicting a process for transferring a pattern from a resist layer into an underlayer after selectively covering the surfaces of the resist layer with a protective layer is shown, in accordance with an embodiment. In an embodiment, the protective layer is selectively deposited over the resist layer after the resist layer is treated. For example, the treatment may comprise a UV exposure or an EUV exposure. The treatment may enhance the selectivity of the deposition of the protective layer.

Referring now to FIG. 3A, a cross-sectional illustration of a portion of a device 300 is shown, in accordance with an embodiment. In an embodiment, the device 300 shown in FIG. 3A may be similar to the device 200 shown in FIG. 2A-2D. For example, a patterning stack 305 may be provided over a substrate (not shown). An underlayer 310 may be provided over the patterning stack 305. In an embodiment, the underlayer 310 may be similar to the underlayer 210 described herein. For example, the underlayer 310 may comprise a fluorine doped carbon layer or a fluorocarbon-based polymer film. That is, the underlayer 210 may comprise fluorine and carbon. A resist layer 320 may be provided over the underlayer 310. The resist layer 320 may be similar to resist layer 220, such as a CAR. In an embodiment, a pattern 325 may be formed in the resist layer 320 with a process similar to the process described above with respect to FIG. 2A-2D.

In an embodiment, a treatment 328 may be applied to the resist layer 320. The treatment 328 may be used to improve the chemical differences between the underlayer 310 and the resist layer 320. In some embodiments, the treatment 328 may include a UV exposure or an EUV exposure. The use of a UV exposure or an EUV exposure initiates the chemical reaction within the resist layer 320 in order to generate chemical species along the surfaces 324 of the resist layer 320. For example, the treatment 328 may result in the formation of an acid and/or amine at the surfaces 324 of the resist layer 320. The presence of the acids and/or amines along with the H-C bonds provide a reactive interface for selectively depositing the protective layer.

Referring now to FIG. 3B, a cross-sectional illustration of the device 300 after the protective layer 330 is selectively deposited over the resist layer 320 is shown, in accordance with an embodiment. In an embodiment, the protective layer 330 may be formed over the top surface and sidewall surfaces of the resist layer 320. Additionally, the selective deposition allows for the exposed surfaces 321 of the underlayer 310 to remain uncovered. Stated differently, a substantial amount of the protective layer 330 may not deposit onto the exposed surfaces 321 of the underlayer 310.

In an embodiment, the protective layer 330 comprises a material that has an etch selectivity relative to the underlayer 310 that is higher than an etch selectivity of the underlayer 310 relative to the resist layer 320. As such, an etching process that removes the underlayer 310 may not substantially remove the protective layer 330. This allows for the structure of the resist layer 320 to remain through the transfer of the pattern 325 into the underlayer 310. In a particular embodiment, the protective layer 330 may comprise an organic material. Other embodiments may include a protective layer 330 that is an organometallic material. For example, the protective layer 330 may be similar to the protective layer 230 described in greater detail herein.

In an embodiment, the protective layer 330 is selectively deposited over the surfaces of the resist layer 320 by leveraging chemical differences between the surfaces of the resist layer 320 and the underlayer 310. As noted above, the underlayer 310 may comprise a surface with C—F bonds that are relatively oleophobic, and the resist layer 320 may comprise a surface 324 with H—C bonds, acids, amines, C═O bonds, O—H bonds, and/or ester groups that are relatively oleophilic. As such, the surfaces 324 of the resist layer 320 are more reactive to the organometallic and/or organic precursors used to deposit the protective layer 330. This allows for the protective layer 330 to substantially surround the remaining structure of the resist layer 320 without significant deposition on the underlayer 310.

Referring now to FIG. 3C, a cross-sectional illustration of the device 300 after the pattern 325 is transferred into the underlayer 310 is shown, in accordance with an embodiment. In an embodiment, the pattern 325 may be transferred into the underlayer 310 through an etching process, such as a dry etching process. Due to the presence of the protective layer 330 over the resist layer 320, the structure of the resist layer 320 substantially persists after the etching process used to transfer the pattern 325 into the underlayer 310. In an embodiment, the etching process may be similar to the etching process described in greater detail herein with respect to FIG. 2F.

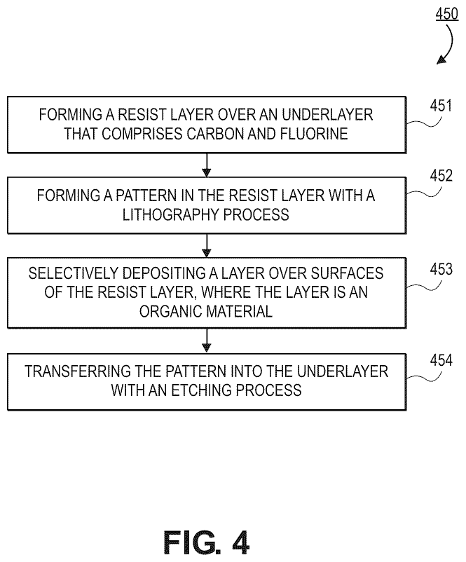

Referring now to FIG. 4, a flow diagram of a process 450 for selectively applying a protective layer over a patterned resist is shown, in accordance with an embodiment. In an embodiment, the process 450 may begin with operation 451, which comprises forming a resist layer over an underlayer that comprises carbon and fluorine. The resist layer may be similar to any of the resist layers described in greater detail herein. For example, the resist layer may be a UV or EUV resist, such as a CAR. The underlayer may comprise a fluorine doped carbon layer or a fluorocarbon-based polymer film. That is, the underlayer 210 may comprise fluorine and carbon.

In an embodiment, the process 450 may continue with operation 452, which comprises forming a pattern in the resist layer with a lithography process. The patterning process may include an EUV or UV exposure and developing process. The resist patterning process may be similar to any of the other resist patterning processes described in greater detail herein.

In an embodiment, the process 450 may continue with operation 453, which comprises selectively depositing a layer over surfaces of the resist layer. In an embodiment, the layer may comprise an organic material or an organometallic material. The protective layer may be selectively deposited on the resist layer using the chemical differences between the resist layer and the underlayer. For example, the deposition process may include a CVD process or an ALD process that reacts with the H—C bonds without the significantly reacting with the C—F bonds of the underlayer. The selective deposition process may be similar to any of the selective deposition processes described in greater detail herein.

In an embodiment, the process 450 may continue with operation 454, which comprises transferring the pattern into the underlayer with an etching process. The etching process may include a plasma etch or the like. Due to the presence of the protective layer over the resist layer, the etching process may not substantially reduce a thickness of the resist layer. As such, subsequent patterning for underlying layers is improved.

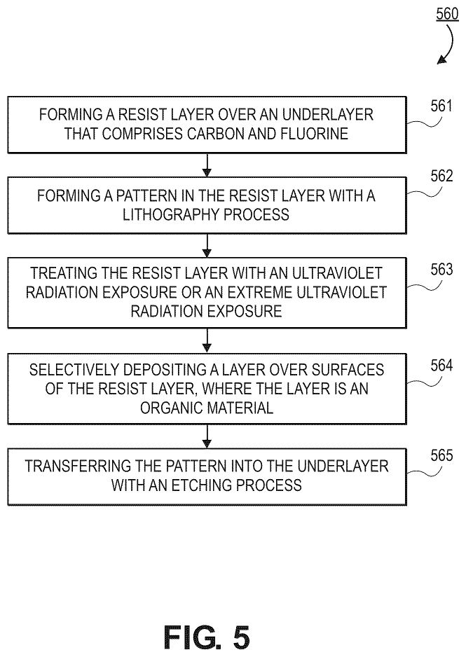

Referring now to FIG. 5, a flow diagram of a process 560 for selectively applying a protective layer over a treated patterned resist is shown, in accordance with an embodiment. In an embodiment, the process 560 may begin with operation 561, which comprises forming a resist layer over an underlayer that comprises carbon and fluorine. In an embodiment, operation 561 may be similar to operation 451 described above. In an embodiment, the process 560 may continue with operation 562, which comprises forming a pattern in the resist layer with a lithography process. The operation 562 may be similar to operation 452 described above.

In an embodiment, the process 560 may continue with operation 563, which comprises treating the resist layer with a UV radiation exposure or an EUV radiation exposure. The additional UV and/or EUV exposure may generate acids and/or amines at the surface of the resist layer. These additional species may be helpful for further improving the selectivity of the deposition of the protective layer in a subsequent processing operation.

In an embodiment, the process 560 may continue with operation 564, which comprises selectively depositing a layer over surfaces of the resist layer. In an embodiment, the layer may comprise an organic material or an organometallic material. In an embodiment, the operation 563 may be similar to operation 453 described above. In an embodiment, the process 560 may continue with operation 565, which comprises transferring the pattern into the underlayer with an etching process. In an embodiment, the operation 565 may be similar to operation 454 described above.

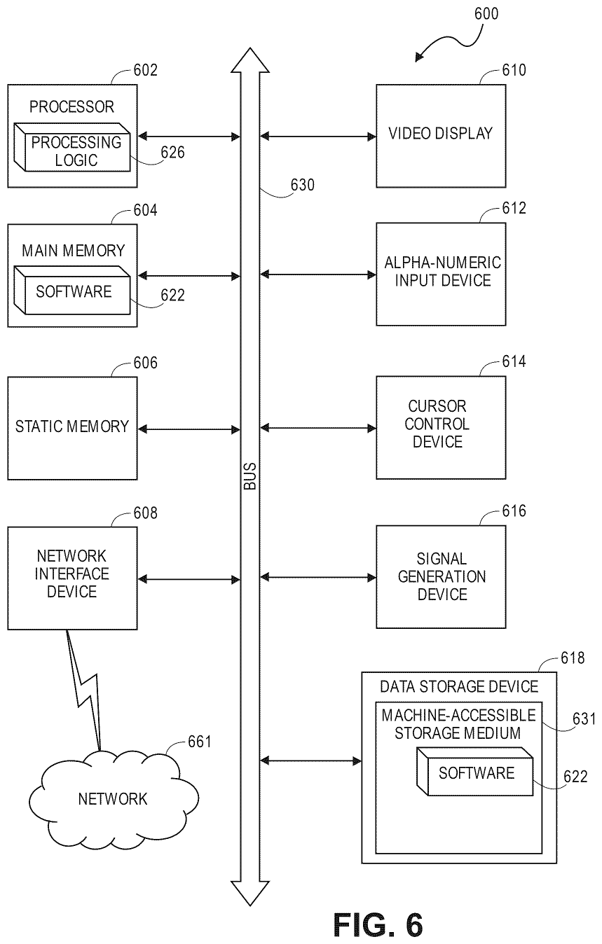

Referring now to FIG. 6, a block diagram of an exemplary computer system 600 of a processing tool is illustrated in accordance with an embodiment. In an embodiment, computer system 600 is coupled to and controls processing in the processing tool. Computer system 600 may be connected (e.g., networked) to other machines in a Local Area Network (LAN), an intranet, an extranet, or the Internet. Computer system 600 may operate in the capacity of a server or a client machine in a client-server network environment, or as a peer machine in a peer-to-peer (or distributed) network environment. Computer system 600 may be a personal computer (PC), a tablet PC, a set-top box (STB), a Personal Digital Assistant (PDA), a cellular telephone, a web appliance, a server, a network router, switch or bridge, or any machine capable of executing a set of instructions (sequential or otherwise) that specify actions to be taken by that machine. Further, while only a single machine is illustrated for computer system 600, the term “machine” shall also be taken to include any collection of machines (e.g., computers) that individually or jointly execute a set (or multiple sets) of instructions to perform any one or more of the methodologies described herein.

Computer system 600 may include a computer program product, or software 622, having a non-transitory machine-readable medium having stored thereon instructions, which may be used to program computer system 600 (or other electronic devices) to perform a process according to embodiments. A machine-readable medium includes any mechanism for storing or transmitting information in a form readable by a machine (e.g., a computer). For example, a machine-readable (e.g., computer-readable) medium includes a machine (e.g., a computer) readable storage medium (e.g., read only memory (“ROM”), random access memory (“RAM”), magnetic disk storage media, optical storage media, flash memory devices, etc.), a machine (e.g., computer) readable transmission medium (electrical, optical, acoustical or other form of propagated signals (e.g., infrared signals, digital signals, etc.)), etc.

In an embodiment, computer system 600 includes a system processor 602, a main memory 604 (e.g., read-only memory (ROM), flash memory, dynamic random access memory (DRAM) such as synchronous DRAM (SDRAM) or Rambus DRAM (RDRAM), etc.), a static memory 606 (e.g., flash memory, static random access memory (SRAM), etc.), and a secondary memory 618 (e.g., a data storage device), which communicate with each other via a bus 630.

System processor 602 represents one or more general-purpose processing devices such as a microsystem processor, central processing unit, or the like. More particularly, the system processor may be a complex instruction set computing (CISC) microsystem processor, reduced instruction set computing (RISC) microsystem processor, very long instruction word (VLIW) microsystem processor, a system processor implementing other instruction sets, or system processors implementing a combination of instruction sets. System processor 602 may also be one or more special-purpose processing devices such as an application specific integrated circuit (ASIC), a field programmable gate array (FPGA), a digital signal system processor (DSP), network system processor, or the like. System processor 602 is configured to execute the processing logic 626 for performing the operations described herein.

The computer system 600 may further include a system network interface device 608 for communicating with other devices or machines. The computer system 600 may also include a video display unit 610 (e.g., a liquid crystal display (LCD), a light emitting diode display (LED), or a cathode ray tube (CRT)), an alphanumeric input device 612 (e.g., a keyboard), a cursor control device 614 (e.g., a mouse), and a signal generation device 616 (e.g., a speaker).

The secondary memory 618 may include a machine-accessible storage medium 631 (or more specifically a computer-readable storage medium) on which is stored one or more sets of instructions (e.g., software 622) embodying any one or more of the methodologies or functions described herein. The software 622 may also reside, completely or at least partially, within the main memory 604 and/or within the system processor 602 during execution thereof by the computer system 600, the main memory 604 and the system processor 602 also constituting machine-readable storage media. The software 622 may further be transmitted or received over a network 661 via the system network interface device 608. In an embodiment, the network interface device 608 may operate using RF coupling, optical coupling, acoustic coupling, or inductive coupling.

While the machine-accessible storage medium 631 is shown in an exemplary embodiment to be a single medium, the term “machine-readable storage medium” should be taken to include a single medium or multiple media (e.g., a centralized or distributed database, and/or associated caches and servers) that store the one or more sets of instructions. The term “machine-readable storage medium” shall also be taken to include any medium that is capable of storing or encoding a set of instructions for execution by the machine and that cause the machine to perform any one or more of the methodologies. The term “machine-readable storage medium” shall accordingly be taken to include, but not be limited to, solid-state memories, and optical and magnetic media.

In the foregoing specification, specific exemplary embodiments have been described. It will be evident that various modifications may be made thereto without departing from the scope of the following claims. The specification and drawings are, accordingly, to be regarded in an illustrative sense rather than a restrictive sense.

What is claimed is:

1. A method, comprising:
forming a resist layer over an underlayer that comprises carbon and fluorine;
forming a pattern in the resist layer with a lithography process;
selectively depositing a layer over surfaces of the resist layer; and
transferring the pattern into the underlayer with an etching process.

2. The method of claim 1, wherein the resist layer is a chemically amplified resist (CAR).

3. The method of claim 1, wherein the layer is an organometallic material.

4. The method of claim 3, wherein the organometallic material comprises BOₓ, BNₓ, TiOₓ, TiNₓ, TaOₓ, TaNₓ, HFOₓ, AlOₓ, SnOₓ, or HfNₓ.

5. The method of claim 1, wherein the organic material comprises C, SiOₓ, or GeOₓ.

6. The method of claim 1, wherein the layer is deposited with an atomic layer deposition (ALD) process or a chemical vapor deposition (CVD) process.

7. The method of claim 1, wherein a surface of the resist layer comprises H—C bonds and a surface of the underlayer comprises C—F bonds, and wherein the H—C bonds preferentially react with a precursor used to deposit the layer so that the layer preferentially forms on the surface of the resist layer and not on the surface of the underlayer.

8. The method of claim 1, further comprising:
applying a treatment to the resist layer after the resist layer is patterned and before forming the layer over exposed surfaces of the resist layer, wherein the treatment comprises an ultraviolet (UV) exposure or an extreme ultraviolet (EUV) exposure.

9. The method of claim 8, wherein the treatment generates acids and/or amines on the exposed surfaces of the resist layer.

10. The method of claim 1, wherein a first etch selectivity between the layer and the underlayer is higher than a second etch selectivity between the resist layer and the underlayer.

11. A method, comprising:
forming an underlayer over a substrate, wherein the underlayer comprises fluorine and carbon;
forming a chemically amplified resist (CAR) over the underlayer;
patterning the CAR with an extreme ultraviolet (EUV) lithography process;
forming a layer over surfaces of the CAR, wherein portions of the underlayer are exposed through openings in the layer;
etching a pattern into the underlayer.

12. The method of claim 11, wherein the layer is an organic layer.

13. The method of claim 12, wherein the layer is an organometallic layer.

14. The method of claim 11, wherein a surface of the underlayer comprises C—F bonds.

15. The method of claim 11, wherein the layer is deposited with an atomic layer deposition (ALD) or chemical vapor deposition (CVD) process.

16. The method of claim 11, wherein a first etch selectivity between the layer and the underlayer is higher than a second etch selectivity between the underlayer and the CAR.

17. The method of claim 11, further comprising:
treating the CAR with an ultraviolet (UV) exposure or an EUV exposure after patterning and before forming the layer.

18. A method, comprising:
providing a patterning stack with a chemically amplified resist (CAR) that is patterned over an underlayer that comprises carbon and fluorine; and
applying a protective layer over surfaces of the CAR with a dry deposition process that comprises an organic precursor and/or an organometallic precursor, and wherein carbon-fluorine bonds at a surface of the underlayer reduce deposition of the protective layer on the underlayer.

19. The method of claim 18, wherein the surfaces of the CAR comprise hydrogen-carbon bonds that are reactive to the organic precursor and/or the organometallic precursor.

20. The method of claim 18, wherein the protective layer comprises BOₓ, BNₓ, TiOₓ, TiNₓ, TaOₓ, TaNₓ, HFOₓ, HfNₓ, C, SiOₓ, AlOₓ, SnOₓ, or GeOₓ.
